(19) United States
(12) Patent Application Publication
(10) Pub. No.: US 2015/0207105 A1
(43) Pub. Date: Jul. 23, 2015

(54) SCATTERING CONDUCTIVE SUPPORT FOR OLED DEVICE, AND OLED DEVICE INCORPORATING IT

(71) Applicant: SAINT-GOBAIN GLASS FRANCE, Courbevoie (FR)

(72) Inventors: Denis Guimard, Paris (FR); Simon Mazoyer, Paris (FR); Guillaume Lecamp, Paris (FR); Vincent Sauvinet, Grenoble (FR)

(73) Assignee: Saint-Gobain Glass France, Courbevoie (FR)

(21) Appl. No.: 14/420,095

(22) PCT Filed: Jul. 18, 2013
(86) PCT No.: PCT/FR2013/051738

§ 371 Date: Feb. 6, 2015

(30) Foreign Application Priority Data
Aug. 8, 2012 (FR) 1257713

(51) Int. Cl. H01L 51/52; H05B 33/06

(52) U.S. Cl. CPC H01L 51/5268; H05B 33/06; H01L 51/5206; G02B 5/021

(57) ABSTRACT

A scattering conductive support for an organic light-emitting diode device includes, in this order, on a substrate, a scattering layer, a high index layer, a lower electrode with a dielectric underlayer, a dielectric crystalline layer, a single metal layer having an electrical conduction role, which is based on silver, with a thickness of less than 6 nm, and an overlayer.

A subject matter of the present invention is a scattering conductive support for an organic light-emitting diode device and an organic light-emitting diode device incorporating it.

Known organic light-emitting systems or OLEDs (Organic Light-Emitting Diodes) comprise one or more organic light-emitting materials supplied with electricity by electrodes generally in the form of two electrically conducting layers framing this (these) material(s).

The light emitted by electroluminescence uses the recombination energy of holes injected from the anode and of electrons injected from the cathode.

Different OLED configurations exist:
bottom emission devices, that is to say devices with a lower (semi)transparent electrode and an upper reflecting electrode;
top emission devices, that is to say devices with an upper (semi)transparent electrode and a lower reflecting electrode;
top and bottom emission devices, that is to say devices with both a lower (semi)transparent electrode and an upper (semi)transparent electrode.

The invention relates to bottom emission OLED devices.

Use is commonly made, for the lower transparent electrode (anode), of a layer based on indium oxide, generally indium oxide doped with tin, better known under the abbreviation ITO, or also of novel electrode structures using a thin metal layer in place of the ITO, in order to manufacture OLED devices emitting a substantially white light for lighting.

Furthermore, an OLED exhibits a low light extraction efficiency: the ratio of the tight which actually exits from the glass substrate to that emitted by the light-emitting materials is relatively low, of the order of 0.25.

This phenomenon is explained in particular by the fact that a certain amount of photons remains trapped in guided modes between the electrodes.

Solutions for improving the efficiency of an OLED, namely for increasing the gain in light extraction, are thus desired.

Application W02012007575A provides, in a first series of examples V.1 to V.3 in table V, OLED devices each with a substrate made of clear glass with a thickness of 1.6 mm, successively comprising:
a scattering layer, for the extraction of light, with a thickness of 50 μm, comprising a matrix made of glass (enamel obtained from molten glass frits) comprising scattering components made of zirconia,
an electrode in the form of a stack of thin layers comprising silver comprising:
   an underlayer for “improvement” of the light transmission, comprising, in this order:
      a first layer made of TiO₂ with a thickness of 65 nm, deposited by sputtering under a reactive Ar/O₂ atmosphere starting from a Ti target,
      a crystallization layer made of ZnₓSn_{y}O_{z} with x+y≧3 and z≦6 (preferably with 95% by weight of zinc with regard to % by weight of all the metals present), deposited by sputtering under a reactive Ar/O₂ atmosphere starting from a target of the SnZn alloy, with a thickness of 5 or 10 nm,
      a single conductive layer comprising silver, with a thickness of 12.5 nm, deposited by sputtering under an argon atmosphere,
   an overlayer comprising:
      a sacrificial layer made of titanium with a thickness of 2.5 nm, deposited by sputtering under an argon atmosphere starting from a Ti target;
      an “insertion” layer with a thickness of 7 nm, made of titanium oxide TiO₂ or aluminum-doped zinc oxide (AZO) or made of ZnₓSn_{y}O_{z} with x+y≧3 and z 6 (preferably with 95% by weight of zinc with regard to % by weight of all the metals present), deposited by sputtering under a reactive Ar/O₂ atmosphere starting from a target of the SnZn alloy;
      a layer for homogenization of the surface electrical properties made of TiN, with a thickness of 1.5 nm, deposited by sputtering under a reactive Ar/N₂ atmosphere starting from a Ti target.

The resistance per square of this electrode is of the order of 4 ohm/square.

The aim set by the invention is that of providing a scattering support with an electrode which makes possible better extraction of the light of an OLED emitting in the white region, thus suitable for the lighting application.

To this end, a first subject matter of the invention is a scattering conductive support for an OLED, comprising (in this order):
a transparent substrate, preferably made of mineral glass, in particular a substrate (glass) with a refractive index n2 of less than or equal to 1.6,
a scattering layer, which (high index) layer is added, in particular which layer is deposited, (directly) on the substrate and/or is formed by a scattering surface (surface rendered scattering) of the substrate, which layer in particular has a thickness of a micron and is preferably mineral (enamel, and the like),
a high index layer, (directly) on the scattering layer, with a refractive index n0 of greater than or equal to 1.8, preferably of greater than or equal to 1.9 and preferably of less than or equal to 2.2, in particular with a thickness of at least 0.2 μm, 0.4 μm, indeed even at least 1 μm, preferably mineral (enamel, and the like), which high index layer is preferably distinct from the scattering layer,
the scattering layer and high index layer combination preferably exhibiting an at least micronic thickness, the high index layer participating or being used in particular in smoothing/planarizing the scattering layer, for example in order to prevent short circuits,
   a first (optionally structured) transparent electrode, referred to as lower electrode, (directly) on the high index layer, and which comprises the following stack of layers in this order (moving away from the substrate):
   a mono- or multilayer dielectric underlayer, preferably thin, in particular made of metal oxide and/or metal nitride, with a refractive index n1 and with a thickness t1 greater than or equal to 0 nm; which underlayer is preferably distinct from the high index layer and is less than 200 nm, indeed even more than 100 nm,
   a dielectric crystalline layer, in particular made of metal oxide and/or metal nitride, referred to as “contact layer”, deposited (directly) on the optional underlayer or (directly) on the high index layer, and with a thickness at least of 3 nm and preferably of less than 15 nm, indeed even preferably of less than 10 nm, which crystalline layer is optionally distinct from the underlayer,
   a single metal layer having the (main) role of electrical conduction, which is based on silver, with a given thickness t2 of less than 6 nm, which layer is preferably positioned (directly) on the contact layer, indeed even on the underlayer, indeed even on a thin metal “underblocker” layer which is less conductive than the silver and which has a thickness of less than 3 nm, in particular made of partially oxidized metal (underblocker on the contact layer or on the underlayer);
   a monolayer or multilayer overlayer, for example thin, deposited (directly) on the single metal layer, indeed even on a thin metal “overblocker” layer which is less conductive than the silver and with a thickness of less than or equal to 3 nm, in particular made of partially oxidized metal, the overlayer being electrically conducting, in particular made of metal oxide and/or metal nitride, and in particular comprises a work-function-matching layer which is preferably the final electrode layer in order to be in contact with the organic light-emitting system.

It is necessary for a maximum of the white light emitted by electroluminescence to reach the scattering components (particles and/or textured surface) which are used for the extraction of the light. In point of fact, the Plasmon guided mode and other guided modes related to the presence of a silver layer coexist and these guided modes can trap the white light in a significant proportion, rendering the light extraction relatively inefficient.

The invention, via the matching of a stack based on a silver monolayer, minimizes the scale of these guided modes and optimizes the extraction of the integrated light via the scattering layer.

Surprisingly, the amount of light trapped in the guided modes is an increasing function of the total amount of silver present in the anode. Consequently, in order to optimize the extraction, it is necessary first to minimize this thickness of silver as much as necessary. In practice, this thickness of silver has to be at least less than 6 nm to compete with a layer of ITO at the risk of increasing the sheet resistance.

As for the patent W02012007575A1, in addition it only provides an increase in the light extraction at normal incidence, but this is only of relatively little advantage as the manufacturers of OLEDs are interested in the light recovered under all angles. The luminance of these OLEDs is measured at the normal and by spectroscopy. In addition, this patent is very particularly devoted to a monochromatic light, that is to say a light centered on one wavelength (green, and the like).

Consequently, the applicant company has established a relevant criterion for evaluating the optical performances, which criterion is the integrated extraction described subsequently.

In the present invention, all the refractive indices are defined at 550 nm.

When the underlayer is a multilayer, for example a bilayer, indeed even a trilayer (preferably all dielectrics), n1 is the mean index defined by the sum of the index nᵢ by thickness tᵢ products of the layers divided by the sum of the respective thicknesses tᵢ, according to the conventional formula n1=Σnᵢtᵢ/Σtᵢ. Naturally, t1 is then the sum of all the thicknesses.

In the present invention, a layer is dielectric in contrast to a metal layer, typically made of metal oxide and/or metal nitride, including by extension silicon or even an organic layer.

In the present invention, the expression based on indicates that the layer predominantly (at least 50% by weight) comprises the component indicated.

In the present invention, the single metal conduction layer or any dielectric layer can be doped. Doping is understood usually as exhibiting a presence of the component in an amount of less than 10% by weight of metal component in the layer. A metal oxide or nitride can be doped in particular between 0.5% and 5%. Any layer of metal oxide according to the invention can be a simple oxide or a mixed oxide which is or is not doped.

Thin layer is understood to mean, according to the invention, a layer with a thickness at most equal to 200 nm (in the absence of further details), preferably deposited under vacuum, in particular by PVD, in particular by (magnetron-assisted) sputtering, indeed even by CVD.

According to the invention, the silver-based layer is the main layer of electrical conduction, that is to say the most conductive layer. The silver-based layer preferably has a thickness of at least 2 nm, indeed even 3 nm.

Within the meaning of the present invention, when it is specified that a deposition of layer or of coating (comprising one or more layers) is carried out directly under or directly on another deposited layer, this means that there cannot be interposition of any layer between these two deposited layers.

Amorphous layer is understood to mean a layer which is not crystalline.

Scattering layer is understood to mean a layer capable of scattering the light emitted by electroluminescence in the visible region.

Within the meaning of the present invention, indium-tin oxide (or else indium oxide doped with tin or ITO) is understood to mean a mixed oxide or a mixture obtained from indium(III) oxide (In₂O₃) and tin(IV) oxide (SnO₂), preferably in the proportions by weight of between 70% and 95% for the first oxide and 5% and 20% for the second oxide. A typical proportion by weight is approximately 90% by weight of In₂O₃ for approximately 10% by weight of SnO₂.

According to the invention, a high index layer (in the absence of further details) has a refractive index of greater than or equal to 1.8, indeed even of greater than or equal to 1.9.

Preferably, the underlayer can exhibit at least one of the following characteristics:
the underlayer is monolayer, bilayer or trilayer,
at least the first layer or base layer is a metal oxide, indeed even all of the layers of the overlayer are made of metal oxide (excluding underblocker),
the underlayer is devoid of indium, or at least does not comprise a layer made of IZO or ITO,
n1 is greater than or equal to 1.9 and preferably less than 2.7,
the underlayer is made of metal oxide and/or of metal nitride and in particular does not comprise a metal layer.

It is preferable in particular for n1 to be greater than or equal to 2.2 and indeed even greater than or equal to 2.3 or 2.4 and, for example, less than 2.8.

In a preferred embodiment, the contact layer is distinct from the underlayer of nonzero thickness has a thickness of less than 15 nm.

The underlayer can be relatively thick without being excessively absorbent, for example ranging up to 200 nm or 150 nm in particular if it is based on silicon nitride, indeed even on tin oxide, or a mixed layer of tin and zinc preferably with at least 30% or predominantly of tin.

However, an underlayer with a thickness t1 of less than 100 nm, indeed even 80 nm or even 50 nm, is preferred. It is the same for the overlayer.

In order to reduce the absorption as much as possible, when the electrode comprises a layer of oxide, which is optionally doped, chosen from ITO, IZO, simple oxide ZnO, then the oxide layer has a thickness of less than 100 nm, indeed even of less than or equal to 50 nm, and even less than or equal to 30 nm.

The underlayer is optionally doped, in particular in order to increase its index.

The underlayer can improve the properties of attachment of the contact layer without notably increasing the roughness of the electrode.

It can in particular concern:
a layer of SiₓN_{y} (in particular Si₃N₄), alone or in a stack,
SnO₂, alone or a stack of SiₓN_{y}/SnO₂ type,
indeed even TiO₂, alone or in a stack of SiₓN_{y}/TiO₂ type.

The high index layer (indeed even the scattering layer on the substrate) preferably covers the main face of the substrate; thus, it is not structured or structurable, even when the electrode is structured (all or in part).

The first layer or base layer of the underlayer, that is to say a layer closest to the high index layer, preferably also covers the main face of the substrate, for example forms a barrier to alkalis (if necessary) and/or an etching (dry and/or wet) stop layer.

Mention may be made, as an example of base layer, of a layer of titanium oxide or tin oxide.

A base layer forming a barrier to alkalis (if necessary) and/or an etching stop layer can be based on silicon oxycarbide (of general formula SiOC), based on silicon nitride (of general formula SiₓN_{y}), very particularly based on Si₃N₄, based on silicon oxynitride (of general formula SiₓO_{y}N_{z}), based on silicon oxycarbonitride (of general formula SiₓO_{y}N,C_{w}), indeed even based on silicon oxide (of general formula SiₓO_{y}), for thicknesses of less than 10 nm.

It is also possible to choose other oxides and/or nitrides and in particular niobium oxide (Nb₂O₅), zirconium oxide (ZrO₂), titanium oxide (TiO₂), alumina (Al₂O₃), tantalum oxide (Ta₂O₅), yttrium oxide or also nitrides of aluminum, of gallium or of silicon and their mixtures, optionally doped with Zr.

It is possible for the nitriding of the base layer to be slightly substoichiometric.

The underlayer (base layer, and the like) can thus be a barrier to the alkalis underlying the electrode. It protects the optional overlying layer or layers from any contamination, in particular the contact layer under the metal conductive layer (contaminants which might result in mechanical defects, such as delaminations); in addition, it preserves the electrical conductivity of the metal conductive layer. It also prevents the organic structure of an OLED device from being contaminated by alkalis, which can considerably reduce the lifetime of the OLED.

The migration of the alkalis can occur during the manufacture of the device, resulting in a lack of reliability, and/or subsequently, reducing its lifetime.

The underlayer can preferably comprise an etching stop layer, essentially covering the high index layer, in particular being the base layer, in particular a layer based on tin oxide, on titanium oxide, on zirconium oxide, indeed even on silica or on silicon nitride.

Very particularly, for reasons of simplicity, the etching stop layer can form part of or be the base layer and can be:
based on silicon nitride, based on silicon oxide or based on silicon oxynitride or based on silicon oxycarbide or also based on silicon oxycarbonitride and with tin in order to reinforce by antietching property, which layer is of general formula SnSiOCN,
or higher index based on titanium oxide (simple or mixed oxide), on zirconium oxide (simple or mixed oxide) or mixed titanium and zirconium oxide.

The etching stop layer serves to protect the base layer and/or the high index layer, in particular in the case of chemical etching or reactive plasma etching; for example has a thickness of at least 2 nm, indeed even 3 nm, indeed even 5 nm.

By virtue of the etching stop layer, the base layer and/or the high index layer are preserved during a liquid-route or dry-route etching stage.

In a preferred embodiment, the underlayer comprises, indeed even consists of, a layer (optionally doped), preferably the base layer, based on titanium oxide on zirconium oxide or on mixed titanium and zirconium oxide, which layer in particular has a thickness of between 3 and 80 nm, indeed even less than 50 nm.

In the case where a crystalline contact layer is not employed, the metal conductive layer can be deposited (directly) on the underlayer for example (as last layer), amorphous layer, for example a layer based on silicon nitride, optionally with underblocker, or based on titanium oxide or made of amorphous SnZnO, typically very rich in Sn (close to SnO₂) or in Zn (close to ZnO).

In the case where an underlayer is not employed, the crystalline contact (mono)layer is directly on the high index layer. A crystalline contact layer promotes the appropriate crystalline orientation of the silver-based layer deposited above.

ITO might be chosen as contact layer. However, preference is given to a contact layer devoid of indium and as efficient as possible for the growth of the silver.

The crystalline contact layer can preferably be based on zinc oxide and can preferably be doped, in particular by at least one of the following dopants; Al (AZO), Ga (GZO), indeed even by B, Sc or Sb, for better deposition process stability. In addition, preference is given to a layer of zinc oxide ZnOₓ, with preferably x less than 1, more preferably still between 0.88 and 0.98, in particular from 0.90 to 0.95.

It is also possible to choose a crystalline contact layer made of SnₓZn_{y}O_{z}, preferably with the following ratio by weight Zn/(Zn+Sn)≧80%, indeed even 85% or 90%.

The thickness of the crystalline contact layer is preferably greater than or equal to 3 nm, indeed even greater than or equal to 5 nm, and can in addition be less than or equal to 15 nm, indeed even less than or equal to 10 nm.

In one configuration, a crystalline underlayer is employed, for example SnZnO or SnO₂, in particular an underlayer which is monolayer, the crystalline contact layer as already described (ZnO, SnZnO, and the like)
is distinct from the underlayer
or else the underlayer includes the crystalline contact layer, with t1 typically greater than 15 nm or 20 nm.

Preferably, the metal conductive layer can be pure or alloyed or doped with at least one other material preferably chosen from: Au, Pd, Al, Pt, Cu, Zn, Cd, In, Si, Zr, Mo, Ni, Cr, Mg, Mn, Co or Sn, in particular is based on an alloy of silver and of palladium and/or of gold and/or of copper, in order to improve the resistance to moisture of the silver.

The substrate according to the invention coated with the lower electrode preferably exhibits a low roughness so that the difference from the hollowest point to the highest point (peak-to-valley difference) on the overlayer is less than or equal to 10 nm.

The substrate according to the invention coated with the lower electrode preferably exhibits, on the overlayer, an RMS roughness of less than or equal to 10 nm, indeed even of less than or equal to 5 nm or 3 nm, preferably even less than or equal to 2 nm, to 1.5 nm, indeed even less than or also equal to 1 nm, in order to avoid spike effects which drastically reduce the lifetime and the reliability, in particular, of the OLED.

The RMS roughness means Root Mean Square roughness. It is a measurement which consists in measuring the value of the standard deviation of the roughness. This RMS roughness, in practical terms, thus quantifies, as mean, the height of the roughness peaks and hollows, with respect to the mean height. Thus, an RMS roughness of 2 nm means a double peak mean amplitude.

It can be measured in different ways: for example, by atomic force microscopy, by a stylus mechanical system (for example using the measurement instruments sold by Veeco under the Dektak name), or by optical interferometry. The measurement is generally carried out over a square micrometer by atomic force microscopy and over a greater surface area, of the order of 50 micrometers² to 2 millimeters², for the stylus mechanical systems.

This low roughness is achieved in particular when the underlayer comprises a smoothing layer, in particular a noncrystalline smoothing layer, said smoothing layer being positioned under the crystalline contact layer (directly or not) and being made of a material other than that of the contact layer.

The smoothing layer is preferably a layer of simple or mixed oxide, which is or is not doped, based on an oxide of one or more of the following metals: Sn, Si, Ti, Zr, Hf, Zn, Ga or In; in particular, it is a layer of mixed oxide based on zinc and tin which is optionally doped or a layer of mixed oxide of indium and tin (ITO) or a layer of mixed oxide of indium and zinc (IZO).

The smoothing layer can in particular be based on a mixed oxide of zinc and tin SnₓZn_{y}O, in amorphous phase, in particular nonstoichiometric, which is optionally doped, in particular with antimony.

This smoothing layer can preferably be on the base layer or even directly on the high index layer.

The following for example are provided under the silver layer (and preferably directly on the high index layer):
amorphous Si₃N₄/SnₓZn_{y}O_{z}/crystalline layer based on ZnO, for example AZO or SnZnO,
amorphous SnO₂/SnₓZn_{y}O_{z}/crystalline layer based on ZnO, for example AZO or SnZnO,
amorphous Zr(Ti)O₂/SnₓZn_{y}O, or TiO₂/crystalline layer based on ZnO, for example AZO or SnZnO,
amorphous SiNx/Sn,Zn_{y}O_{z}/crystalline layer based on ZnO, for example AZO or SnZnO,
amorphous SnₓZn_{y}O_{z}/crystalline layer based on ZnO, for example AZO or SnZnO.

Thus, the underlayer comprises, indeed even is composed of:
titanium oxide, zirconium oxide, or mixed oxide of titanium and zirconium, or
silicon nitride/titanium oxide, zirconium oxide or mixed oxide of titanium and zirconium, or
titanium oxide, zirconium oxide, mixed oxide of titanium and zirconium/amorphous mixed oxide based on zinc and tin, or
silicon nitride or tin oxide/amorphous mixed oxide based on zinc and tin, which underlayer is preferably surmounted by a crystalline layer based on ZnO.

Preferably, the overlayer can exhibit at least one of the following characteristics:
be monolayer, bilayer or trilayer,
at least the first layer (excluding overblocker) is a metal oxide, indeed even all the layers of the overlayer are made of metal oxide,
the combined layers of the overlayer exhibit a thickness of less than or equal to 120 nm, indeed even of less than or equal to 80 nm,
have a greater (mean) index than the substrate, for example greater than or equal to 1.8.

Furthermore, in order to promote the injection of current and/or to limit the value of the operating voltage, it is possible to provide, preferably, for the overlayer to be composed of layer(s) (excluding the thin blocking layer described subsequently) having an electrical resistivity (in the bulk state, as known in the literature) of less than or equal to 10⁷ ohm·cm, preferably of less than or equal to 10⁶ ohm·cm, indeed even of less than or equal to 10⁴ ohm·cm.

It is also possible to avoid any layer which forms an etching stop by its nature, indeed even its thickness (TiO₂, SnO₂, or the like).

The overlayer is preferably based on thin layer(s) which are in particular mineral.

The overlayer according to the invention is preferably based on a simple or mixed oxide, based on at least one of the following metal oxides, which is (are) optionally doped: tin oxide, indium oxide, zinc oxide (optionally substoichiometric), molybdenum oxide, tungsten oxide or vanadium oxide.

This overlayer can in particular be made of tin oxide optionally doped by F or Sb or made of zinc oxide optionally doped with aluminum, or can optionally be based on a mixed oxide, in particular a mixed oxide of indium and tin (ITO), a mixed oxide of indium and zinc (IZO) or a mixed oxide of zinc and tin SnₓZn_{y}O_{z}.

This overlayer, particularly for ITO, IZO (generally final layer) or based on ZnO, can preferably exhibit a thickness t3 of less than or equal to 50 nm, or 40 nm, or even 30 nm, for example between 10 nm or 15 nm and 30 nm.

The ITO is preferably superstoichiometric in oxygen in order to reduce its absorption (typically to less than 1%).

The overlayer can comprise a layer based on ZnO, which is crystalline (AZO, SnZnO, or the like) or amorphous (SnZnO), which is not the final layer and, for example, is the same layer as the underlayer.

Generally, the silver-based layer is covered with an additional thin layer exhibiting a higher work function typical of ITO. A work-function-matching layer can, for example, have a work function WF starting from 4.5 eV and preferably greater than or equal to 5 eV.

The overlayer comprises preferably, as final layer, in particular work-function-matching layer, a layer which is based on a simple or mixed oxide, based on at least one of the following metal oxides, which is optionally doped: indium oxide, zinc oxide (optionally substoichiometric), molybdenum oxide MoO₃, tungsten oxide WO₃, vanadium oxide V₂O₅, ITO, IZO or SnₓZn_{y}O_{z}, and the overlayer preferably exhibits a thickness of less than or equal to 50 nm, indeed even 40 nm or even 30 nm.

The overlayer can comprise a final layer, in particular a work-function-matching layer, which is based on a thin metal layer (less conductive than silver), in particular based on nickel, platinum or palladium, for example with a thickness of less than or equal to 5 nm, in particular from 1 to 2 nm, and preferably separated from the metal conductive layer (or the layer of an overblocker) by an underlying layer made of simple or mixed metal oxide.

The overlayer can comprise, as final dielectric layer, a layer with a thickness of less than 5 nm, indeed even 2.5 nm, and of at least 0.5 nm, indeed even 1 nm, chosen from a nitride, an oxide, a carbide, an oxynitride or an oxycarbide, in particular of Ti, Zr, Ni or NiCr.

The lower electrode according to the invention is easy to manufacture, in particular by choosing for the materials of the stack materials which can be deposited at ambient temperature. More preferably still, the majority, indeed even all, of the layers of the stack are deposited under vacuum (preferably successively), preferably by cathode sputtering, optionally magnetron cathode sputtering, making significant gains in productivity possible.

In order to further reduce the cost of the lower electrode, it may be preferable for the total thickness of material comprising (preferably predominantly comprising, that is to say with a percentage by weight of indium of greater than or equal to 50%) indium of this electrode to be less than or equal to 60 nm, indeed even less than or equal to 50 nm, 40 nm, indeed even less than or equal to 30 nm. Mention may be made, for example, of ITO or IZO as layer(s), the thicknesses of which it is preferable to limit.

Provision can also be made for one, indeed even two, very thin coating(s), known as “blocking coating”, positioned directly under, on or on each side of the silver metal layer.

The underblocking coating underlying the silver metal layer, in the direction of the substrate, or underblocker is an attaching, nucleating and/or protective coating.

It acts as protective or “sacrificial” coating in order to prevent the detrimental change in the silver layer by attack and/or migration of oxygen from a layer which surmounts it, indeed even also by migration of oxygen if the layer which surmounts it is deposited by cathode sputtering in the presence of oxygen.

The silver metal layer can thus be deposited directly on at least one underlying blocking coating.

The silver metal layer can also or alternatively be directly under at least one overlying blocking coating, or overblocker, each coating exhibiting a thickness preferably of between 0.5 and 5 nm.

At least one blocking coating (preferably overblocker) preferably comprises a metal, metal nitride and/or metal oxide layer based on at least one of the following metals: Ti, V, Mn, Fe, Co, Cu, Zn, Zr, Hf, Al, Nb, Ni, Cr, Mo, Ta or W, or based on an alloy of at least one of said materials, preferably based on Ni or Ti, based on an Ni alloy or based on an NiCr alloy.

For example, a blocking coating (preferably overblocker) can be composed of a layer based on niobium, tantalum, titanium, chromium or nickel or on an alloy starting from at least two of said metals, such as a nickel/chromium alloy.

A thin blocking layer (preferably overblocker) forms a protective layer, indeed even a “sacrificial” layer, which makes it possible to prevent the detrimental change in the metal of the silver metal layer, in particular in one and/or other of the following configurations:
if the layer which surmounts the metal conductive layer is deposited by using a reactive plasma (oxygen, nitrogen, and the like), for example if the oxide layer which surmounts it is deposited by cathode sputtering,
if the composition of the layer which surmounts the conductive metal layer is capable of varying during the industrial manufacture (change in the conditions of deposition, wear type, of a target, and the like), in particular if the stoichiometry of a layer of oxide and/or nitride type changes, thus modifying the quality of the silver metal layer and thus the properties of the electrode (sheet resistance, light transmission, and the like),
if the electrode is subjected, subsequent to deposition, to a heat treatment.

Preference is given in particular to a thin blocking layer (preferably overblocker) based on a metal chosen from niobium Nb, tantalum Ta, titanium Ti, chromium Cr or nickel Ni or on an alloy starting from at least two of these metals, in particular on an alloy of niobium and tantalum (Nb/Ta), of niobium and chromium (Nb/Cr), of tantalum and chromium (Ta/Cr) or of nickel and chromium (Ni/Cr). This type of layer, based on at least one metal, exhibits a particularly high getter effect.

A thin metal blocking layer (preferably overblocker) can be easily manufactured without detrimentally affecting the metal conductive layer. This metal layer can preferably be deposited in an inert atmosphere (that is to say, without deliberate introduction of oxygen or nitrogen) consisting of noble gas (He, Ne, Xe, Ar or Kr). It is not ruled out or harmful for, at the surface, this metal layer to be oxidized during the subsequent deposition of a layer based on metal oxide.

The thin metal blocking layer (preferably overblocker) makes it possible in addition to obtain an excellent mechanical strength (resistance to abrasion, in particular to scratches).

Nevertheless, for the use of metal blocking layer (preferably overblocker), it is necessary to limit its thickness and thus the light absorption in order to retain a light transmission sufficient for transparent electrodes.

The thin blocking layer (preferably overblocker) can be partially oxidized of the MOₓ type, where M represents the material and x is a number lower than the stoichiometry of the oxide of the material, or of the MNOₓ type, for an oxide of two materials M and N (or more). Mention may be made, for example, of TiOₓ or NiCrOₓ.

x is preferably between 0.75 times and 0.99 times the normal stoichiometry of the oxide. For a monoxide, x can in particular be chosen between 0.5 and 0.98 and, for a dioxide, x can in particular be chosen between 1.5 and 1.98.

In a specific alternative form, the thin blocking layer (preferably overblocker) is based on TiOₓ and x can in particular be such that 1.5≦x≦1.98 or 1.5<x<1.7, indeed even 1.7≦x≦1.95.

The thin blocking layer (preferably overblocker) can be partially nitrided. It is thus not deposited in the stoichiometric form but in the substoichiometric form, of the MN_{y} type, where M represents the material and y is a number lower than the stoichiometry of the nitride of the material. y is preferably between 0.75 times and 0.99 times the normal stoichiometry of the nitride.

In the same way, the thin blocking layer (preferably overblocker) can also be partially oxynitrided.

This thin oxidized and/or nitrided blocking layer (preferably overblocker) can be easily manufactured without detrimentally affecting the functional layer. It is preferably deposited from a ceramic target, in an unoxidizing atmosphere preferably consisting of noble gas (He, Ne, Xe, Ar or Kr).

The thin blocking layer (preferably overblocker) can preferably be made of substoichiometric nitride and/or oxide for yet greater reproducibility of the electrical and optical properties of the electrode.

The thin substoichiometric oxide and/or nitride blocking layer (preferably overblocker) chosen can preferably be based on a metal chosen from at least one of the following metals: Ti, V, Mn, Fe, Co, Cu, Zn, Zr, Hf, Al, Nb, Ni, Cr, Mo, Ta or W, or on a substoichiometric oxide of an alloy based on at least one of these materials.

Preference is given in particular to a layer (preferably overblocker) based on an oxide or oxynitride of a metal chosen from niobium Nb, tantalum Ta, titanium Ti, chromium Cr or nickel Ni or of an alloy starting from at least two of these metals, in particular of an alloy of niobium and tantalum (Nb/Ta), of niobium and chromium (Nb/Cr), of tantalum and chromium (Ta/Cr) or of nickel and chromium (Ni/Cr).

It is also possible to choose, as substoichiometric metal nitride, a layer made of silicon nitride SiNₓ or of aluminum nitride AlNₓ or of chromium nitride CrNₓ or of titanium nitride TiNₓ or of nitride of several metals, such as NiCrNₓ.

The thin blocking layer (preferably overblocker) can exhibit an oxidation gradient, for example M(N)Oₓᵢ with xᵢ variable; the part of the blocking layer in contact with the metal layer is less oxidized than the part of this layer which is most distant from the metal layer, using a specific deposition atmosphere.

All the layers of the electrode are preferably deposited by a vacuum deposition technique but, however, it is not ruled out for one or more layers of the stack to be able to be deposited by another technique, for example by a thermal decomposition technique of pyrolysis type.

In a first embodiment, the scattering layer is a layer added to, for example deposited on, the substrate, which is preferably nontextured, with a high index matrix (n3 greater than 1.8, indeed even greater than or equal to 1.9) and scattering components in particular of mineral type with a refractive index n_{d} td the difference in absolute value between n_{d} and n3 is typically greater than 0.1.

In this first embodiment, the high index layer can be:
the upper region of this scattering layer (for example monolayer, for example layer of at least 1 μm, indeed even 5 μm), for example with a thickness t0 of greater than 0.2 μm, 0.5 μm, indeed even than 1 μm, which region is devoid of scattering components (for example no scattering particles) or at least in a lower amount than an underlying region,
and/an additional layer, deposited on the scattering layer, for example with a thickness t0 of greater than 0.2 μm, indeed even than 1 μm, and even more, devoid of scattering components (for example no addition of scattering particles) or at least in a lower amount than the scattering layer.

This does not prevent the scattering layer from itself being a monolayer with a gradient of scattering components or even a bilayer with a gradient of scattering components and/or distinct (nature and/or concentration) scattering components.

A scattering layer in the form of a polymer matrix comprising scattering particles, for example described in EP 1 406 474, is possible.

In a preferred implementation of this first embodiment, the scattering layer is a mineral layer on the substrate, in particular a glass layer, with a high index mineral matrix (the index n3), for example made of oxide(s), in particular an enamel, and scattering components, in particular of mineral type (pores, precipitated crystals, solid or hollow particles, for example of oxides or non-oxide ceramics) with a refractive index n_{d} td the difference in absolute value between n_{d} and n3 is greater than 0.1.

Preferably, the high index layer is mineral, for example made of oxide(s), in particular a glass layer, and especially an enamel.

The high index layer preferably has a matrix identical to that of the scattering layer. When the matrices are identical, the interface between the scattering layer and the high index layer is not “marked”/observable, even if deposited one after the other.

Such enamel layers are known in the art and are described, for example, in EP 2 178 343 and WO2011/089343 or in the patent application of the prior art already described.

Although the chemical nature of the scattering particles is not particularly limited, they are preferably chosen from TiO₂ and SiO₂ particles. For an optimum extraction efficiency, they are present in a concentration of between 10⁴ and 10⁷ particles/mm². The greater the size of the particles, the more their optimum concentration is located towards the lower limit of this range.

The scattering enamel layer generally has a thickness of between 1 μm and 100 μm, in particular between 2 μm and 30 μm. The scattering particles dispersed in this enamel preferably have a mean diameter, determined by DLS (dynamic light scattering), of between 0.05 μm and 5 μm, in particular between 0.1 μm and 3 μm.

Under the scattering layer, it is possible to add a layer which is a barrier to alkalis, deposited on the substrate made of mineral glass, or a layer which is a barrier to moisture on the plastic substrate, which layer is based on silicon nitride, on silicon oxycarbide, on silicon oxynitride, on silicon oxycarbonitride or on silica, alumina, on titanium oxide, on tin oxide, on aluminum nitride or on titanium nitride, for example with a thickness of less than or equal to 10 nm and preferably of greater than or equal to 3 nm, indeed even 5 nm. It can be a multilayer, in particular for a layer which is a barrier to moisture.

In a second (alternative or cumulative) embodiment, the scattering layer is formed by a surface texturing, which is preferably nonperiodical, in particular random, for the white light application. The substrate formed of a mineral or organic glass is textured or a textured layer is added to (deposited on) a mineral or organic glass (thus forming a composite substrate). The high index layer is over the top.

Rough interfaces intended to extract the light emitted by the organic layers of the OLEDs are also known and are described, for example, in the applications WO2010/112786, WO02/37568 and WO2011/089343. The surface roughness of the substrate can be obtained by any known appropriate means, for example by acid etching (hydrofluoric acid), sandblasting or abrasion. The high index layer is preferably mineral, based on oxide(s), in particular an enamel. It is preferably at least 1 μm, indeed even 5 μm or even 10 μm in thickness.

A means for extracting the light can also be located on the external face of the substrate, that is to say the face which will be opposite that turned towards the lower electrode. It can be a network of microlenses or micropyramids, as described in the paper in Japanese Journal of Applied Physics, Vol. 46, No. 7A, pages 4125-4137 (2007), or else a satin finishing, for example a satin finishing by frosting with hydrofluoric acid.

The substrate can be flat or curved and in addition rigid, flexible or semi-flexible.

Its main faces can be rectangular, square or even of any other shape (round, oval, polygonal, and the like). This substrate can be large in size, for example with a surface area of greater than 0.02 m², indeed even 0.5 m² or 1 m², and with a lower electrode (optionally divided into several “electrode surface” zones) occupying substantially the surface (apart from the structuring zones and/or the edge zones).

The substrate is substantially transparent. It can exhibit a light transmittance T_{L} of greater than or equal to 70%, preferably greater than or equal to 80%, indeed even greater than or equal to 90%.

The substrate can be mineral or made of plastic, such as polycarbonate PC or polymethyl methacrylate PMMA or also a polyethylene naphthalate PEN, a polyester, a polyimide, a polyestersulfone PES, a PET, a polytetrafluoroethylene PTFE, a sheet of thermoplastic material, for example polyvinylbutyral PVB, polyurethane PU, made of ethylene/vinyl acetate EVA or made of multi- or single-component resin, which can be thermally crosslinked (epoxy, PU) or which can be crosslinked using ultraviolet radiation (epoxy, acrylic resin), and the like.

The substrate can preferably be an item of glass, made of mineral glass, made of silicate glass, in particular made of soda-lime or soda-lime-silica glass, a clear glass, an extraclear glass or a float glass. It can be a high index glass (in particular with an index of greater than 1.6).

The substrate can advantageously be a glass exhibiting an absorption coefficient of less than 2.5 m⁻¹, preferably of less than 0.7 m⁻¹, at the wavelength of the OLED radiation.

For example, soda-lime-silica glasses with less than 0.05% of Fe(III) or of Fe₂O₃ are chosen, in particular the Diamant glass from Saint-Gobain Glass, the Optiwhite glass from Pilkington or the B270 glass from Schott. It is possible to choose all the extraclear glass compositions described in the document WO04/025334.

With an emission of the OLED system through the thickness of the transparent substrate, a portion of the radiation emitted is guided in the substrate. Consequently, in an advantageous design of the invention, the thickness of the glass substrate chosen can be at least 1 mm, preferably at least 5 mm, for example. This makes it possible to reduce the number of internal reflections and to thus extract more guided radiation in the glass, thus enhancing the luminance of the light zone.

The OLED device can be back-emitting and optionally also front-emitting, depending on whether the upper electrode is reflecting or semi-reflecting, or even transparent (in particular with a T_{L} comparable to the anode, typically from 60% and preferably greater than or equal to 80%).

In order to produce substantially white light, several methods are possible: mixture of compounds (red, green, blue emission) in a single layer, stacking three organic structures (red, green, blue emission) or two organic structures (yellow and blue) on the face of the electrodes.

The OLED device can be adjusted in order to produce, at the outlet, a (substantially) white light, as close as possible to the (0.33, 0.33) coordinates or the (0.45, 0.41) coordinates, in particular at 0°.

The white light can be defined in the CIE XYZ colorimetric diagram by the standard ANSI C78.377-2008 in the instructions entitled “Specifications for the chromaticity of solid state lighting products”, pages 11-12.

The OLEDs are generally divided into two main families, according to the organic material used.

If the light-emitting layers are small molecules, reference is made to SM-OLED (Small Molecule Organic Light Emitting Diodes).

Generally, the structure of an SM-OLED consists of a stack of a Hole Injection Layer (HIL), a Hole Transporting Layer (HTL), an emissive layer and an Electron Transporting Layer (ETL).

Examples of organic light-emitting stacks are, for example, described in the document entitled “Four wavelength white organic light emitting diodes using 4,4′-bis[carbazoyl-(9)]stilbene as a deep blue emissive layer” by C. H. Jeong et al., published in Organics Electronics, 8 (2007), pages 683-689.

If the organic light-emitting layers are polymers, reference is made to PLEDs (Polymer Light-Emitting Diodes).

The OLED organic layer or layers generally have an index starting from 1.8, indeed even beyond (1.9 even more).

A final subject matter of the invention is an OLED device incorporating the scattering conductive support as defined above and an OLED system above the lower electrode and emitting polychromatic radiation, preferably white light.

Preferably, the OLED device can comprise an OLED system which is more or less thick, for example between 50 nm and 350 nm or 300 nm, particularly between 90 nm and 130 nm, indeed even between 100 nm and 120 nm.

There exist OLED devices comprising a highly doped HTL (Hole Transport Layer) layer as described in U.S. Pat. No. 7,274,141.

There exist OLED systems with a thickness of between 100 and 500 nm, typically 350 nm, or thicker OLED systems, for example with a thickness of 800 nm, as described in the paper entitled “Novaled PIN OLED® Technology for High Performance OLED Lighting” by Philip Wellmann, relating to the Lighting Korea 2009 conference.

In addition, a subject matter of the present invention is a process for the manufacture of the scattering conductive support according to the invention and of the OLED according to the invention.

The process comprises, of course, the deposition of the scattering layer and of the high index layer (preferably distinct from the scattering layer), preferably high index mineral layer, in particular to form enamel (molten glass frit), for example using silk screen printing.

The process also, of course, comprises the deposition of the successive layers constituting the lower electrode. The deposition of the majority, indeed even all, of these layers preferably takes place by magnetron cathode sputtering.

The process according to the invention, in addition, preferably comprises a stage of heating the lower electrode at a temperature of greater than 180° C., preferably of greater than 200° C., in particular of between 230° C. and 450° C. and ideally between 300° C. and 350° C., for a period of time preferably of between 5 minutes and 120 minutes, in particular between 15 minutes and 90 minutes.

During this heating (annealing) stage, the electrode of the present invention experiences a noteworthy improvement in the electrical and optical properties.

The invention will now be described in more detail using nonlimiting examples.

### EXAMPLES

In an example 1 according to the invention, an OLED device comprises a mineral glass (refractive index n2=1.5 at λ=550 nm) of 0.7 mm with, on one and the same main face, in this order:
a scattering layer made of a high index enamel (n3=1.95 at λ=550 nm), for example composed of a bismuth-rich matrix, and comprising TiO₂ particles (mean diameter 400 nm) or in an alternative form SiO₂ particles (mean diameter 300 nm), with a thickness of 15 μm; particle density TiO₂ is of the order of 5×10⁸ particles/mm³ and particle density for the SiO₂ is 2×10⁶ particles/mm³,
a high index layer, for example composed of the same bismuth-rich matrix (n0=1.95 at λ=550 nm), without addition of scattering particles, of micronic thickness, deposited on the scattering layer.

The scattering layer+high index layer assembly is known hereinafter as IEL.

A lower electrode is deposited by cathode sputtering on this high index layer, which lower electrode forms a transparent anode comprising:
a dielectric underlayer (which is here a bilayer),
a crystalline layer, referred to as contact layer,
a single metal layer having an electrical conduction role, which is based on silver,
an overblocker,
an overlayer.

The organic layers (HTL/EBL (Electron Blocking Layer)/EL/HBL(Hole Blocking Layer)/ETL) are deposited by vacuum evaporation so as to produce an OLED which emits white light. Finally, a metal cathode made of silver and/or of aluminum is deposited by vacuum evaporation directly on the stack of organic layers.

By way of comparison, two comparative examples representative of the prior art with regard to ITO and a reference example which does not form part of the prior art or of the invention are manufactured. The details of all the examples and of their electrical and optical performances are in table 1 below. In addition, the IEL described above is chosen for comparative example 2 and the reference example.

TABLE 1

| | Examples | | | | |
|---|---|---|---|---|---|
| | Comparative | Comparative | Comparative | Reference | |
| | 1 | 2 | 3 | example | Example 1 |
| Scattering | ITO | IEL + ITO | IEL + 12 nm Ag | IEL + 8 nm Ag | IEL + Ag < 6 nm |
| conductive | | | | | |
| substrate | | | | | |
| Glass [mm] | 0.7 | 0.7 | 0.7 | 0.7 | 0.7 |
| Internal light | No | Yes | Yes | Yes | Yes |
| extraction, | | | | | |
| referred to as IEL | | | | | |
| Breakdown of the | | | | | |
| electrode | | | | | |
| Si₃N₄ [nm] | — | — | 20 | 20 | 20 |
| SnZnO [nm] | — | — | 5 | 5 | 5 |
| AZO [nm] | — | — | 5 | 5 | 5 |
| Ag [nm] | — | — | 12 | 8 | 5.8 |
| Ti [nm] | — | — | 0.3 | 0.3 | 0.3 |
| ITO [nm] | 180 | 180 | 15 | 15 | 15 |
| Post-deposition | Yes | Yes | Yes | Yes | Yes |
| annealing | | | | | |
| Absorption | 3.8% | 3.8% | 4.9% | 4.1% | 3.8% |
| measured on glass | | | | | |
| (without EL stack) | | | | | |
| R□ | 10.5 | 10.5 | 3.1 | 5.7 | 9.1 |
| Total EQE | 7.2% | 10.8% | 10.0% | 10.3% | 11.5% |

Only an electrode comprising Ag, with a thickness <6 nm, exhibits better performances than ITO. In addition, the R□ remains better than that of ITO. The thicker reference example gives a better R□ but at the expense of the EQE (external quantum efficiency, measured in an integrating sphere, which is the ratio of the number of photons emitted to the number of electrons injected).

Si₃N₄ is doped with aluminum, just like the zinc oxide. SnZnO is amorphous and doped with Sb.

The deposition conditions for each of the layers are as follows:
the layer based on Si₃N₄:Al is deposited by reactive sputtering using a silicon target doped with aluminum, under a pressure of 0.25 Pa in an argon/nitrogen atmosphere,
the layer based on SnZnOx:Sbₓ is deposited by reactive sputtering using a zinc and tin target doped with antimony comprising by weight, for example 65% of Sn, 34% of Zn and 1% of Sb, or alternatively comprising, by weight, 50% of Sn, 49% of Zn and 1% of Sb, under a pressure of 0.2 Pa and in an argon/oxygen atmosphere,
the layer of ZnO:Al is deposited by reactive sputtering using an aluminum-doped zinc target, under a pressure of 0.2 Pa and in an argon/oxygen atmosphere, or alternatively with a ceramic target,
the layer of silver is deposited using a silver target, under a pressure of 0.8 Pa in an atmosphere of pure argon,
the layer of Ti is deposited using a titanium target, under a pressure of 0.8 Pa in an atmosphere of pure argon,
the overlayer of ITO is deposited using a ceramic target comprising 90% by weight of indium oxide and 10% by weight of tin oxide in an argon/oxygen atmosphere, the ITO being superstoichiometric in oxygen.

The Ti overblocker layer can be partly oxidized after deposition of the ITO over the top.

Before the deposition of the organic light-emitting stack, for example immediately after the deposition of the lower electrode, the scattering conductive support is advantageously annealed at 230° C., indeed even at 300° C., in order to further improve the electrical and optical properties. The duration of the annealing is typically at least 10 min and, for example, less than 1 h 30.

As alternative examples as underlayer, mention may be made of:
SiO₂, for example approximately with t1 from 2 to 32 nm, indeed even to 24 nm or to 14 nm,
SnO₂ or SiNₓ or SnZnO (amorphous or crystalline), for example with t1 from 2 to 30 nm,
SnO₂/amorphous SnZnO, for example from 2 to 30 nm, in particular SnZnO with a thickness of less than 10 nm,
ZrO₂, for example with t1 from 2 to 50 nm, indeed even from 2 to 15 nm, or (Ti)ZrOₓ,
TiO₂, for example from 2 to 50 nm, indeed even from 2 to 25 nm,
TiO₂, for example from 2 to 50 nm, indeed even 2 to 25 nm/amorphous SnZnO preferably and preferably less than 10 nm.

It is also possible not to place an underlayer under the crystalline layer AZO.

The lower electrode can, in an alternative form, comprise an underlying blocking coating, in particular comprising, like the overlying blocking coating, a metal layer preferably obtained by a metal target with a neutral plasma, or a layer made of nitride and/or oxide of one or more metals, such as Ti, Ni or Cr, preferably obtained by a ceramic target with a neutral plasma.

Mention may be made, as alternative overlayer, of:
IZO (preferably as final layer, thus replacing ITO) with a thickness of less than 50 nm, indeed even of less than or equal to 35 nm or even 20 nm,
amorphous SnZnO or crystalline layer based on ZnO, for example under or replacing the ITO, with a thickness of less than 50 nm, indeed even of less than or equal to 35 nm,
MoO₃, WO₃, V₂O₅ (preferably as final layer, thus replacing ITO),
ZnₓSn_{y}O_{z} with x+y≧3 and z≦6, for example surmounted by TiN with a thickness of 1 to 2 nm.

Alternatively or cumulatively, a textured glass is chosen, for example a glass having a roughness obtained, for example, with hydrofluoric acid. The high index layer planarizes the textured glass.

1. A scattering conductive support for an organic light-emitting diode, comprising, in this order:
a transparent substrate;
a scattering layer, which is a layer on the substrate and/or formed by a scattering surface of the substrate;
a high index layer, with a refractive index n0 of greater than or equal to 1.8, and
a first transparent electrode, which comprises the following stack of layers, in this order:
a dielectric underlayer with a refractive index n1 and with a thickness t1 of greater than or equal to 0 nm,
a dielectric crystalline contact layer,
a single metal layer having an electrical conduction role, which is based on silver, with a given thickness t2 of less than 6 nm,
an electrically conducting overlayer.

2. The scattering conductive support as claimed in claim 1, wherein t1 is nonzero and n1 is greater than or equal to 2.2.

3. The scattering conductive support as claimed in claim 1, wherein t1 is nonzero and the underlayer comprises a layer based on titanium oxide, on zirconium oxide or on a mixed oxide of titanium and zirconium.

4. The scattering conductive support as claimed in claim 1, wherein the underlayer comprises a layer of mixed oxide based on zinc and tin, and/or a layer made of silicon nitride.

5. The scattering conductive support as claimed in claim 1, wherein, when the first transparent electrode comprises an optionally doped layer of oxide chosen from ITO, IZO or the simple oxide ZnO, then the layer of oxide has a thickness of less than or equal to 50 nm.

6. The scattering conductive support as claimed in claim 1, wherein the underlayer comprises:
titanium oxide, or zirconium oxide, or mixed oxide of titanium and zirconium,
silicon nitride/titanium oxide, zirconium oxide, or mixed oxide of titanium and zirconium,
titanium oxide, zirconium oxide, or mixed oxide of titanium and zirconium/amorphous mixed oxide based on zinc and tin, or
silicon nitride or tin oxide/amorphous mixed oxide based on zinc and tin, which underlayer is surmounted by a crystalline layer based on ZnO.

7. The scattering conductive support as claimed in claim 1, wherein, under the single metal layer, no layer comprises indium and the total thickness of material comprising indium in the first transparent electrode is less than or equal to 60 nm.

8. The scattering conductive support as claimed in claim 1, wherein the dielectric crystalline contact layer is based on optionally doped zinc oxide, or a layer of mixed oxide of zinc and tin; the contact layer having a thickness of less than 10 nm.

9. The scattering conductive support as claimed in claim 1, wherein the single metal layer is directly under at least one first overlying overblocking coating which comprises a metal, metal nitride and/or metal oxide layer based on at least one of the following metals: Ti, V, Mn, Fe, Co, Cu, Zn, Zr, Hf, Al, Nb, Ni, Cr, Mo, Ta or W, or based on an alloy of at least one of said materials.

10. The scattering conductive support as claimed in claim 1, wherein the overlayer comprises a layer based on at least one of the following metal oxides, which is optionally doped: indium oxide, zinc oxide (optionally substoichiometric), molybdenum oxide MoO₃, tungsten oxide WO₃, vanadium oxide V₂O₅, ITO, IZO or SnₓZn_{y}O_{z}, and/or wherein the overlayer comprises a final layer which is based on a thin metal layer.

11. The scattering conductive support as claimed in claim 1, wherein the overlayer comprises, as final dielectric layer, a layer with a thickness of less than 5 nm, and of at least 0.5 nm chosen from a nitride, an oxide, a carbide, an oxynitride or an oxycarbide.

12. The scattering conductive support as claimed in claim 1, wherein the scattering layer is a layer on the substrate, with a high index matrix with a refractive index n3 greater than or equal to 1.8, and scattering components.

13. The scattering conductive support as claimed in claim 1, wherein the scattering layer is a textured and nonperiodical surface of the substrate.

14. An organic light-emitting device incorporating a support as claimed in claim 1 and an organic light-emitting system over the first transparent electrode and configured to emit polychromatic radiation.

15. A process for the manufacture of the scattering conductive support as claimed in claim 1 comprising heating the first transparent electrode at a temperature of greater than 180° C. for a period of time between 5 minutes and 120 minutes.
